(19) United States
(12) Patent Application Publication
(10) Pub. No.: US 2021/0009865 A1
(43) Pub. Date: Jan. 14, 2021

(54) ADHESIVE COMPOSITION, AND ADHESIVE LAYER-EQUIPPED LAYERED PRODUCT USING SAME

(71) Applicant: TOAGOSEI CO., LTD., Tokyo (JP)

(72) Inventors: Yuya OKIMURA, Nagoya-shi (JP); Makoto HIRAKAWA, Nagoya-shi (JP); Masashi YAMADA, Aichi (JP)

(21) Appl. No.: 16/978,274

(22) PCT Filed: Mar. 1, 2019
(86) PCT No.: PCT/JP2019/008052

§ 371 Date: Sep. 4, 2020

(30) Foreign Application Priority Data
Mar. 7, 2018 (JP) 2018-041341

(51) Int. Cl. C09J 123/26; C09J 123/14; C09J 123/20; C09J 123/08; C09J 151/06; C09J 163/00; C09J 11/06; B32B 15/08; B32B 15/20; B32B 7/12

(52) U.S. Cl. CPC C09J 123/26; B32B 2457/08; C09J 123/20; C09J 123/08; C09J 151/06; C09J 163/00; C09J 11/06; B32B 15/08; B32B 15/20; B32B 7/12; C09J 2301/16; C09J 2423/04; C09J 2423/10; C09J 2423/16; C09J 2451/00; C09J 2463/00; B32B 2250/02; B32B 2307/204; B32B 2311/12; B32B 2379/08; C09J 123/14

(57) ABSTRACT

Provided is an adhesive composition that is characterized by containing a modified polypropylene-based resin (A), an epoxy resin (B) and an unmodified polypropylene-based resin (C), with the modified polypropylene-based resin (A) being a resin obtained by graft modifying an unmodified polypropylene-based resin (D) with a modifying agent that contains an α,β-unsaturated carboxylic acid or a derivative thereof, the content of the modified polypropylene-based resin (A) being 10 mass % or more in terms of solid content, and the content of the unmodified polypropylene-based resin (C) being 1-90 mass % in terms of solid content. The adhesive composition exhibits good adhesion to a copper foil or a base material film comprising a polyimide resin or the like, and exhibits improved dielectric properties.

### TECHNICAL FIELD

The present invention relates to an adhesive composition and a laminate having an adhesive layer using the same. In further detail, it relates to an adhesive composition and a laminate having an adhesive layer suitable for use in bonding electronic parts and the like, particularly for manufacturing products related to flexible printed circuits (hereinafter often referred to as “FPC”).

### BACKGROUND ART

Since the flexible printed circuit can be mounted three-dimensionally with high density even within a limited space, their application is expanding. Recently, as electronic devices become more compact and lightweight, the products related to flexible printed circuits are diversifying and the demand for them is increasing. As such products related to FPC, there can be mentioned a flexible copper clad laminate in which a copper foil is bonded to a polyimide film; a flexible printed circuit in which an electronic circuit is formed on the flexible copper clad laminate; a reinforced flexible printed circuit in which the flexible printed circuit is bonded to a reinforcing board; a multilayered board having flexible copper clad laminates or flexible printed circuits layered and bonded with each other; a flexible flat cable (hereinafter often referred to as “FFC”) comprising copper wiring bonded to a base film, and the like. For example, when the flexible copper clad laminate is manufactured, an adhesive is usually used for bonding the polyimide film and the copper foil together.

Further, when the flexible printed circuit is manufactured, a film so-called “coverlay film” is generally used for protecting wired portions. The coverlay film consists of an insulating resin layer and an adhesive layer formed thereon, and a polyimide resin composition is widely used for forming the insulating resin layer. In manufacturing the flexible printed circuits, the coverlay film is bonded to the surface having wiring portions thereon via the adhesive layer by means of, for instance, a heat press. In this instance, the adhesive layer of the coverlay film is required to establish a strong adhesion to both the wiring portions and the base film layer.

In addition, as a printed circuit, a build-up multilayer printed circuit in which a conductor layer and an organic insulator layer are alternately layered on a surface of a substrate is known. When such a multilayer printed circuit is manufactured, a material forming an insulating adhesive layer, so-called a “bonding sheet”, is used for bonding the conductor layer and the organic insulator layer. The insulating adhesive layer is required to have embeddability to the wiring portions and establish a strong adhesion to both materials of the conductor portions forming the circuit (copper and the like) and the organic insulator layer (polyimide resins and the like).

As adhesives for use in the FPC related products, there have been proposed epoxy-based adhesive compositions containing a thermoplastic resin highly reactive with the epoxy resin. For instance, Patent Document 1 discloses an adhesive that is based on an ethylene-acrylate copolymer rubber and an epoxy resin. Furthermore, Patent Document 2 discloses an adhesive that is based on a glycidyl group-containing thermoplastic elastomer and an epoxy resin. Moreover, Patent Document 3 discloses an adhesive that is based on a styrene-maleic acid copolymer and an epoxy resin. Adhesive compositions described in theses references are widely used because they perform fast curing reaction and have excellent adhesiveness by virtue of reactivity of carboxylic groups of the rubber or elastomer components with the epoxy resin.

Furthermore, in the field of mobile communication equipment such as mobile phones and information terminal devices which are now rapidly increasing in demand, higher frequency signals are used to process a huge amount of data at high speed. Accordingly, with the increase in signal speed and signal frequency, the adhesive for use in FPC-related products must satisfy dielectric properties that can withstand use in high frequency region (low dielectric constant and low dielectric loss tangent). To cope with such demands for dielectric properties, for example, Patent Document 4 discloses an epoxy resin composition containing an epoxy resin, a copolymer resin made from, as essential components, an aromatic vinyl compound and maleic anhydride, and a specific phenol compound. Moreover, Patent Document 5 discloses an adhesive composition containing a modified polyolefin resin and an epoxy resin, which has specific contents of the modified polyolefin resin and the epoxy resin.

### CONVENTIONAL TECHNICAL DOCUMENTS

### Patent Documents

Patent Document 1: Japanese Patent Publication (Laid-open) No. H7(1995)-235767.
Patent Document 2: Japanese Patent Publication (Laid-open) No. 2001-354936.
Patent Document 3: Japanese Patent Publication (Laid-open) No. 2007-2121.
Patent Document 4: Japanese Patent Publication (Laid-open) No. H10(1998)-17685.
Patent Document 5: International Publication No. WO 2016/047289.

### SUMMARY OF INVENTION

### Problems to be Solved by the Invention

However, with the increase in signal frequency as described above, the adhesive compositions disclosed in Patent Documents 1-4 are problematic in that their dielectric properties in the ultra-high frequency microwave region (1 to 3 GHz) are poor. In addition, laminates with adhesive layers of these adhesive compositions sometimes warp before thermosetting (in B stage), and therefore they suffer from the problem of bad workability during the FPC production process. A thinner base film is required to improve the above dielectric properties, however, even when the base film is made thinner, it is still desired that the warpage of the laminate having the adhesive layer is suppressed. Furthermore, the laminate having an adhesive layer of these adhesive compositions is problematic in that it sometimes warps during storage and thus is inferior in storage stability in the laminate state.

The adhesive composition described in Patent Document 5 is excellent in adhesiveness and dielectric properties as well as storage stability when used in a laminate as an adhesive layer thereof, but further improvement in dielectric properties is required in order to cope with the further increase in signal speed and the further increase in signal frequency in recent years.

The present invention has been made in light of the above described problems, and aims at providing an adhesive composition which is excellent in adhesion to base films made from polyimide resins and the like or copper foils, and is further improved in dielectric properties. The present invention also aims at providing a laminate having an adhesive layer, which is further improved in dielectric properties, suppressed in warpage, and excellent in storage stability.

### Means for Solving the Problems

The present inventors have found that an adhesive composition containing a modified polypropylene-based resin, an epoxy resin, and an unmodified polypropylene-based resin in which the contents of the above modified polypropylene-based resin and the above unmodified polypropylene-based resin are within specific amounts exhibits excellent adhesiveness and more improved dielectric properties. In addition, a laminate with an adhesive obtained from this adhesive composition in which the layer of the adhesive is in B-stage exhibits not only excellent adhesiveness but also little warpage and excellent storage stability. The present invention has been accomplished based on these findings.

One aspect of the present invention provides an adhesive composition which comprises a modified polypropylene-based resin (A), an epoxy resin (B), and an unmodified polypropylene-based resin (C), in which the modified polypropylene-based resin (A) is a resin resulting from graft-modification of an unmodified polypropylene-based resin (D) with a modifying agent comprising an α,β-unsaturated carboxylic acid or derivative thereof, the content of the modified polypropylene-based resin (A) is 10 parts by mass or more relative to 100 parts by mass of the solid content of the adhesive composition, and the content of the unmodified polypropylene-based resin (C) is 1 part by mass or more and 90 parts by mass or less relative to 100 parts by mass of the solid content of the adhesive composition.

According to a preferred embodiment of the present invention, the derivative of the α,β-unsaturated carboxylic acid is at least one selected from the group consisting of itaconic anhydride, maleic anhydride, aconitic anhydride, and citraconic anhydride.

According to another preferred embodiment of the present invention, the content percentage of the grafted portions derived from the α,β-unsaturated carboxylic acid or derivative thereof is from 0.1 to 20 mass % relative to 100 mass % of the modified polypropylene-based resin (A).

According to another preferred embodiment of the present invention, the epoxy resin (B) is a multi-functional epoxy resin having an alicyclic structure.

According to another preferred embodiment of the present invention, the propylene copolymerization ratio of the modified polypropylene-based resin (A) is 70 mass % or less.

According to another preferred embodiment of the present invention, the propylene copolymerization ratio of the unmodified polypropylene-based resin (C) is 70 mass % or less.

According to another preferred embodiment of the present invention, the unmodified polypropylene-based resin (C) and the unmodified polypropylene-based resin (D) are each at least one selected from the group consisting of ethylene-propylene copolymers, propylene-butene copolymers, and ethylene-propylene-butene copolymers.

According to another preferred embodiment of the present invention, the adhesive composition comprises an antioxidant.

According to another preferred embodiment of the present invention, the adhesive composition further comprises an organic solvent, and the modified polypropylene-based resin (A), the epoxy resin (B), and the unmodified polypropylene-based resin (C) are dissolved in the organic solvent.

According to another preferred embodiment of the invention, the organic solvent comprises an alicyclic hydrocarbon solvent that is methylcyclohexane and/or cyclohexane, and an alcohol-based solvent, and the content of the alicyclic hydrocarbon relative to 100 parts by mass of the organic solvent is 20 parts by mass or more and 90 parts by mass or less, and the content of the alcohol-based solvent relative to 100 parts by mass of the organic solvent is 1 part by mass or more and 20 parts by mass or less.

According to another preferred embodiment of the present invention, the adhesive composition comprises toluene as the organic solvent.

According to another preferred embodiment of the present invention, the solid content of the adhesive composition comprising the organic solvent is 5 mass % or more and 50 mass % or less.

Another aspect of the present invention provides a laminate having an adhesive layer, which comprises an adhesive layer formed of the adhesive composition of the present invention, and a base film contacting at least one of the surfaces of the adhesive layer, wherein the adhesive layer is in B-stage.

According to another preferred embodiment of the present invention, the base film is at least one selected from the group consisting of a polyimide film, a polyether ether ketone film, a polyphenylene sulfide film, an aramid film, a polyethylene naphthalate film, a liquid crystal polymer film, a polyethylene terephthalate film, a polyethylene film, a polypropylene film, a silicone-treated release paper, a polyolefin resin coated paper, a TPX film, a fluorine-based resin film, and a copper foil.

Another aspect of the present invention provides a printed wiring board which comprises an adhesive layer formed of the adhesive composition of the present invention.

Another aspect of the present invention provides a flexible flat cable which comprises an adhesive layer formed of the adhesive composition of the present invention.

In the present description, the “propylene-based resin” means a resin having a monomer unit derived from propylene. The term “unmodified” means that the resin is not modified with an α,β-unsaturated carboxylic acid or derivative thereof.

In the present description, a weight average molecular weight (hereinafter often referred to as “Mw”) is a standard polystyrene equivalent measured by gel permeation chromatography (hereinafter often referred to as “GPC”).

In the present description, “(meth)acrylic” means acrylic or methacrylic.

### Advantageous Effects of Invention

The adhesive composition of the present invention has good adhesion to a base film comprising a polyimide resin or the like or a copper foil, and is excellent in dielectric properties (low dielectric constant and low dielectric loss tangent). The laminate having the adhesive layer using the present adhesive composition shows little warpage, and thus exhibits excellent workability in the manufacturing processes of various types of components, and favorable storage stability of the laminates. Accordingly, the adhesive composition of the present invention and the laminate having the adhesive layer using the same are suitable for manufacture and the like of the FPC-related products.

### Description of Embodiments

Embodiments of the present invention will be explained below; however, the present invention is not limited thereto.

1. Adhesive Composition

An adhesive composition of the present invention contains a modified polypropylene-based resin (A), an epoxy resin (B), and an unmodified polypropylene-based resin (C) in which the above modified polypropylene-based resin (A) is a resin resulting from graft-modification of an unmodified polypropylene-based resin (D) with a modifying agent comprising an α,β-unsaturated carboxylic acid or derivative thereof, the content of the above modified polypropylene-based resin (A) is 10 parts by mass or more relative to 100 parts by mass of the solid content of the above adhesive composition, and the content of the above unmodified polypropylene-based resin (C) is 1 part by mass or more and 90 parts by mass or less relative to 100 parts by mass of the solid content of the above adhesive composition. Hereinafter, the matters specifying the present invention will be specifically described.

1.1. Modified polypropylene-Based Resin (A)

The modified polypropylene-based resin (A) is a resin having a portion derived from an unmodified polypropylene-based resin (D) and a grafted portion derived from a modifying agent, and is preferably obtained by graft-polymerizing the modifying agent including an α,β-unsaturated carboxylic acid or derivative thereof in the presence of the unmodified polypropylene-based resin (D). The modified polypropylene-based resin (A) can be produced by graft polymerization by a known method, and a radical initiator may be used in the manufacturing. Examples of the method for manufacturing the above modified polypropylene-based resin (A) include a solution method in which the unmodified polypropylene-based resin (D) is heated and dissolved in a solvent such as toluene and the above modifying agent and the radical initiator are added, and a melting method in which the unmodified polypropylene-based resin (D), a modifying agent, and a radical initiator are melt-kneaded by using a Banbury mixer, kneader, extruder, or the like. The method of using the unmodified polypropylene-based resin (D), the modifying agent, and the radical initiator is not particularly limited, and these may be added to the reaction system all at once or may be added sequentially.

In the case of manufacturing the above modified polypropylene-based resin (A), a modification aid for improving the grafting efficiency of α,β-unsaturated carboxylic acid, a stabilizer for adjusting the resin stability, and the like can be further used.

The unmodified polypropylene-based resin (D) used for manufacturing the modified polypropylene-based resin (A) has a structural unit derived from propylene, and is not particularly limited as long as it is not modified with an α,β-unsaturated carboxylic acid or derivative thereof, and a copolymer of propylene and olefins having 2 or more and 20 or less carbon atoms such as ethylene, butene, pentene, hexene, heptene, octene, and 4-methyl-1-pentene is preferably used. In the present invention, a copolymer of propylene and an olefin having 2 or more and 6 or less carbon atoms is particularly preferable.

Adhesive compositions used for bonding electronic parts or the like are sometimes stored at a low temperature of about 5° C. for a period of several days to several months in order to stabilize the solution, and are gelled during the storage so that fluidity disappears. Therefore, the adhesive compositions used for this purpose are also required to have storage stability at low temperatures. From the viewpoint of obtaining storage stability at low temperatures, the propylene copolymerization ratio in the modified polypropylene-based resin (A) is preferably 70 mass % or less, and more preferably 68 mass % or less. In addition, from the viewpoint of imparting flexibility to the bonded portion after bonding the two members while obtaining excellent adhesiveness, the lower limit of the propylene copolymerization ratio in the modified polypropylene-based resin (A) is preferably 50 mass % or more. The structural units other than propylene in the unmodified polypropylene-based resin (D) and the content percentage thereof can be optionally selected as long as the propylene copolymerization ratio in the modified polypropylene-based resin (A) is the above upper limit or less. When adhesion to an adherend that is hard to bond is carried out, the above modified polypropylene-based resin (A) is preferably a resin resulting from the modification of the unmodified polypropylene-based resin (D) that is at least one selected from the group consisting of ethylene-propylene, propylene-butene, and ethylene-propylene-butene copolymers. The molecular weight of the unmodified polypropylene-based resin (D) is not particularly limited.

The modifying agent includes an α,β-unsaturated carboxylic acid or derivative thereof. Examples of the α,β-unsaturated carboxylic acid include maleic acid, fumaric acid, tetrahydrophthalic acid, itaconic acid, citraconic acid, crotonic acid, aconitic acid, norbornene dicarboxylic acid, and (meth)acrylic acid. In addition, examples of the above derivative of the α,β-unsaturated carboxylic acid include acid anhydrides, acid halides, amides, imides, and esters. As the above modifying agent, polycarboxylic acid is preferable, and itaconic anhydride, maleic anhydride, aconitic anhydride, and citraconic anhydride are more preferable, and itaconic anhydride and maleic anhydride are particularly preferable in terms of adhesiveness. The modifying agent may include at least one selected from the α,β-unsaturated carboxylic acids and derivatives thereof, and examples thereof include a combination of one or more of the α,β-unsaturated carboxylic acids and one or more of derivatives thereof, a combination of two or more of the α,β-unsaturated carboxylic acids, or a combination of two or more of the derivatives of the α,β-unsaturated carboxylic acids.

The modifying agent according to the present invention can comprise another compound (another modifying agent) in addition to the α,β-unsaturated carboxylic acid and the like or the derivative thereof in accordance with purposes. Examples of such another compound (another modifying agent) include (meth)acrylates represented by the following formula (1), other (meth)acrylic acid derivatives, aromatic vinyl compounds, cyclohexyl vinyl ether and the like. Such another compound can be used alone or in combination of two or more.

CH₂═CR¹COOR² (1)

(wherein R¹ is a hydrogen atom or a methyl group, and R² is a hydrocarbon group.)

In the above formula (1) representing (meth)acrylates, R¹ is a hydrogen atom or a methyl group, and preferably a methyl group. R² is a hydrocarbon group and preferably an alkyl group with 8 to 18 carbon atoms. Examples of the compounds represented by the above formula (1) include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, decyl (meth)acrylate, lauryl (meth)acrylate, tridecyl (meth)acrylate, stearyl (meth)acrylate, cyclohexyl (meth)acrylate, benzyl (meth)acrylate and the like. These compounds can be used alone or in combination of two or more. Since heat resistive adhesiveness is improved, a modifying agent further comprising a (meth)acrylate with an alkyl group having 8-18 carbon atoms is preferably used, and particularly preferably one comprising octyl (meth)acrylate, lauryl (meth)acrylate, tridecyl (meth)acrylate or stearyl (meth)acrylate is used, in the present invention.

Examples of the derivatives of (meth)acrylic acid other than the (meth)acrylate include hydroxyethyl (meth)acrylate, glycidyl (meth)acrylate, isocyanate-containing (meth)acrylic acids and the like. Examples of the aromatic vinyl compounds include styrene, o-methyl styrene, p-methyl styrene, α-methyl styrene and the like. By using, as a modifying agent, the α,β-unsaturated carboxylic acid or derivative thereof in combination with another modifying agent, graft ratio can be improved, solvent solubility can be improved, or adhesiveness can further be improved. When another modifying agent than the (meth)acrylates represented by the above formula (1) is used, it is desirable that the amount of use thereof does not exceed the total of the amount of use of the α,β-unsaturated carboxylic acid and derivatives thereof and the amount of use of the (meth)acrylates.

As mentioned above, the modified polypropylene-based resin (A) has a grafted portion derived at least from the modifying agent. Hereinafter, the content percentage (hereinafter often referred to as “graft mass”) of the grafted portions contained in the modified polypropylene-based resin (A) is described.

The above modified polypropylene-based resin (A) has a grafted portion derived from the α,β-unsaturated carboxylic acid or derivative thereof. In the modified polypropylene-based resin (A), the graft mass of the grafted portion derived from the α,β-unsaturated carboxylic acid or derivative thereof is preferably 0.1 to 20 mass %, and more preferably 0.2 to 18 mass % relative to 100 mass % of the modified polypropylene-based resin (A) from the viewpoint of adhesiveness. When the graft mass is 0.1 mass % or more, solvent solubility is excellent, and adhesion to adherends made from a metal or the like is particularly excellent.

Also, when the graft mass is 20 mass % or less, sufficient adhesion to adherends made from resins or the like can be obtained.

The graft mass derived from the α,β-unsaturated carboxylic acid or derivative thereof in the above modified polypropylene-based resin (A) can be determined by alkalimetric titration, however, when the derivative of the α,β-unsaturated carboxylic acid is imide or others having no acid group, the graft mass can be determined by Fourier-transform infrared spectroscopy.

When the modified polypropylene-based resin (A) comprises a grafted portion derived from (meth)acrylates represented by the above formula (1), the graft mass thereof is preferably 0.1 to 30 mass % and more preferably 0.3 to 25 mass % relative to 100 mass % of the modified polypropylene-based resin (A). When the graft mass is 0.1 to 30 mass %, solvent solubility is excellent, and if another resin or elastomer as described later is contained, compatibility therewith is excellent, so that adhesion to adherends can further be improved.

When the modifying agent comprises a (meth)acrylate represented by the above formula (1), the graft mass in the obtained modified polypropylene-based resin (A) can be determined by Fourier-transform infrared spectroscopy.

The radical initiator used for manufacture of the modified polypropylene-based resin (A) can arbitrarily be selected from the conventional ones, and those preferably used are, for example, organic peroxides such as benzoyl peroxide, dicumyl peroxide, lauroyl peroxide, di-t-butyl peroxide, 2,5-dimethyl-2,5-di(t-butylperoxy)hexane, and cumene hydroperoxide.

Examples of the modifying aid which can be used for manufacture of the modified polypropylene-based resin (A) include divinyl benzene, hexadiene, and dicyclopentadiene. Examples of the stabilizer include hydroquinone, benzoquinone, and nitrosophenylhydroxy compounds.

The weight average molecular weight (Mw) of the modified polypropylene-based resin (A) is preferably 30,000 to 250,000, and more preferably 50,000 to 200,000. When the weight average molecular weight (Mw) is from 30,000 to 250,000, the adhesive composition can be made excellent in not only solvent solubility and initial adhesion to adherends but also solvent resistance of bonded portions after cured.

The acid value of the modified polypropylene-based resin (A) is preferably from 0.1 to 50 mg KOH/g, more preferably from 0.5 to 40 mg KOH/g, and furthermore preferably from 1.0 to 30 mg KOH/g. When the acid value is from 0.1 to 50 mg KOH/g, the adhesive composition can be cured sufficiently to achieve excellent adhesiveness, heat resistance, and resin flow.

The content of the modified polypropylene-based resin (A) should be 10 parts by mass or more, preferably 30 parts by mass or more, and more preferably 40 parts by mass or more relative to 100 parts by mass of the solid content of the adhesive composition. The content of the modified polypropylene-based resin (A) of the above lower limit value or more allows heat resistance during solder reflow to be improved.

The content of the modified polypropylene-based resin (A) is preferably 99 parts by mass or less relative to 100 parts by mass of the solid content of the adhesive composition.

1.2. Epoxy Resin (B)

Hereinafter, explanation of another component in the above adhesive composition, i.e., epoxy resin (B), is given. The epoxy resin (B) reacts with the carboxyl group of the above modified polypropylene-based resin (A) to realize high adhesion to adherends and heat resistance of cured products of the adhesive.

Examples of the epoxy resin (B) include, but are not limited to, a bisphenol A type epoxy resin, a bisphenol F type epoxy resin, or a hydrogenated product thereof; glycidyl ester type epoxy resins such as diglycidyl orthophthalate, diglycidyl isophthalate, diglycidyl terephthalate, glycidyl p-hydroxybenzoate, diglycidyl tetrahydrophthalate, diglycidyl succinate, diglycidyl adipate, diglycidyl sebacate, and triglycidyl trimellitate; glycidyl ether type epoxy resins such as ethylene glycol diglycidyl ether, propylene glycol diglycidyl ether, 1,4-butanediol diglycidyl ether, 1,6-hexanediol diglycidyl ether, trimethylolpropane triglycidyl ether, pentaerythritol tetraglycidyl ether, tetraphenylglycidylether ethane, triphenylglycidylether ethane, polyglycidyl ethers of sorbitol, and polyglycidyl ethers of polyglycerol; glycidylamine type epoxy resins such as triglycidyl isocyanurate and tetraglycidyl diaminodiphenylmethane; and linear aliphatic epoxy resins such as epoxidized polybutadiene and epoxidized soybean-oil. Also usable are novolac type epoxy resins such as phenol novolac epoxy resin, o-cresol novolac epoxy resin and bisphenol A novolac epoxy resin.

Furthermore, examples of the epoxy resin (B) include a brominated bisphenol A type epoxy resin, a phosphorus-containing epoxy resin, an epoxy resin having dicyclopentadiene structure, an epoxy resin having naphthalene structure, an anthracene type epoxy resin, a tertiary butylcatechol type epoxy resin, a triphenylmethane type epoxy resin, a tetraphenylethane type epoxy resin, a biphenyl type epoxy resin, and a bisphenol S type epoxy resin. These epoxy resins may be used alone or in combination of two or more.

Among the above epoxy resins, preferred are those having no glycidylamino group because the storage stability of the laminate having an adhesive layer can be improved. In addition, an epoxy resin having an alicyclic skeleton is preferable, and an epoxy resin having a dicyclopentadiene skeleton is more preferable, because an adhesive composition having excellent dielectric properties can be obtained.

The epoxy resin (B) for use in the present invention is preferably one having two or more epoxy groups per one molecule. This is because it reacts with the modified polypropylene-based resin (A) to form a crosslinking structure and realize high thermal resistance. In addition, when an epoxy resin having two or more epoxy groups is used, sufficient crosslinking with the modified polypropylene-based resin (A) is formed to establish sufficient thermal resistance.

Preferably, the content of the above epoxy resin (B) is from 1 to 20 parts by mass relative to 100 parts by mass of the above modified polypropylene-based resin (A). More preferably, the above content is from 3 to 15 parts by mass. If the content is 1 part by mass or more, sufficient adhesiveness or thermal resistance may be obtained. In addition, if the content is 20 parts by mass or less, peel adhesion strength or dielectric properties may be improved.

1.3. Unmodified Polypropylene-Based Resin (C)

The unmodified polypropylene-based resin (C) has a structural unit derived from propylene, and is not particularly limited as long as it is not modified with an α,β-unsaturated carboxylic acid or derivative thereof, and a copolymer of propylene and olefins having 2 or more and 20 or less carbon atoms such as ethylene, butene, pentene, hexene, heptene, octene, and 4-methyl-1-pentene is preferably used. In the present invention, a copolymer of propylene and an olefin having 2 or more and 6 or less carbon atoms is particularly preferable. From the viewpoint of obtaining storage stability at low temperatures, the propylene copolymerization ratio in the unmodified polypropylene-based resin (C) is preferably 70 mass % or less, and more preferably 68 mass % or less. In addition, from the viewpoint of imparting flexibility to the bonded portion after bonding the two members while obtaining excellent adhesiveness, the lower limit of the propylene copolymerization ratio in the unmodified polypropylene-based resin (C) is preferably 50 mass % or more. The structural units other than propylene in the unmodified polypropylene-based resin (C) and the content percentage thereof can be optionally selected as long as the propylene copolymerization ratio in the unmodified polypropylene-based resin (C) is the above upper limit or less, and when adhesion to an adherend that is hard to bond is carried out, the above unmodified polypropylene-based resin (C) is preferably ethylene-propylene, propylene-butene, or ethylene-propylene-butene copolymer. The molecular weight of the unmodified polypropylene-based resin (C) is not particularly limited.

The above unmodified polypropylene-based resin (C) has preferably a weight average molecular weight (Mw) of 30,000 to 250,000, more preferably 50,000 to 200,000. When the weight average molecular weight (Mw) is from 30,000 to 250,000, the adhesive composition can be made excellent in not only solvent solubility and initial adhesion to adherends but also solvent resistance of bonded portions after cured.

The content of the unmodified polypropylene-based resin (C) should be 1 part by mass or more and 90 parts by mass or less, preferably 20 parts by mass or more and 70 parts by mass or less, and more preferably 30 parts by mass or more and 60 parts by mass or less relative to 100 parts by mass of the solid content of the adhesive composition. The content of the unmodified polypropylene-based resin (C) within the above range allows dielectric properties to be improved while thermal resistance during solder reflow is maintained.

In the adhesive composition according to the present invention, the total content of the modified polypropylene-based resin (A) and the unmodified polypropylene-based resin (C) is preferably 50 parts by mass or more, and more preferably 60 parts by mass or more relative to 100 parts by mass of the solid content of the adhesive composition. The above total content of 50 parts by mass or more allows flexibility to be imparted to the adhesive layer and prevents warpage of the laminate.

In addition, the above total content is preferably 99 parts by mass or less relative to 100 parts by mass of the solid content of the adhesive composition.

The adhesive composition according to the present invention is characterized in that it comprises the predetermined amounts of the modified polypropylene-based resin (A), the epoxy resin (B), and the unmodified polypropylene-based resin (C), and exhibits a dielectric constant (ε) lower than 2.2 as measured at a frequency of 1 GHz after the adhesive has been made into a cured body. When the dielectric constant is lower than 2.2, the composition is suitable for application to the FPC-related products that cope with higher signal speeds and higher signal frequencies in recent years. In addition, it is preferable that the cured body of the adhesive has a dielectric loss tangent (tan δ) lower than 0.001 as measured at a frequency of 1 GHz. When the dielectric loss tangent is lower than 0.001, FPC-related products excellent in dielectric properties can be produced. Since the dielectric constant and the dielectric loss tangent can be adjusted according to the ratio of the modified polypropylene-based resin (A), the epoxy resin (B), and the unmodified polypropylene-based resin (C) in the adhesive composition, various types of the adhesive compositions can be designed depending on the usage. The methods for measuring the dielectric constant and the dielectric loss tangent will be described later.

1.4. Other Components

The above adhesive composition can contain not only the modified polypropylene-based resin (A), the epoxy resin (B), and the unmodified polypropylene-based resin (C) but also a thermoplastic resin other than the modified polypropylene-based resin (A) and the unmodified polypropylene-based resin (C), a tackifier, a flame retardant, a curing agent, a curing accelerator, a coupling agent, an anti-thermal aging agent, a leveling agent, an antifoaming agent, an inorganic filler, a pigment, and a solvent in amounts not affecting the function of the adhesive composition.

(Thermoplastic Resin)

Examples of the above other thermoplastic resins include phenoxy resins, polyamide resins, polyester resins, polycarbonate resins, polyphenylene oxide resins, polyurethane resins, polyacetal resins, polyethylene resins, polypropylene resins, and polyvinyl resins. These thermoplastic resins may be used either alone or in combination of two or more.

(Tackifier)

Examples of the above tackifiers include coumarone-indene resins, terpene resins, terpene-phenol resins, rosin resins, p-t-butylphenol-acetylene resins, phenol-formaldehyde resins, xylene-formaldehyde resins, petroleum-based hydrocarbon resins, hydrogenated hydrocarbon resins, and turpentine-based resins. These tackifiers may be used alone or in combination of two or more.

(Flame Retardant)

The flame retardant may be either an organic flame retardant or an inorganic flame retardant. Examples of organic flame retardants include phosphorus based flame retardants such as melamine phosphate, melamine polyphosphate, guanidine phosphate, guanidine polyphosphate, ammonium phosphate, ammonium polyphosphate, ammonium phosphate amide, ammonium polyphosphate amide, carbamoyl phosphate, carbamoyl polyphosphate, aluminum trisdiethylphosphinate, aluminum tri smethylethylphosphinate, aluminum tri sdiphenylphosphinate, zinc bisdiethylphosphinate, zinc bismethylethylphosphinate, zinc bisdiphenylphosphinate, titanyl bisdiethylphosphinate, titanium tetrakisdiethylphosphinate, titanyl bismethylethylphosphinate, titanium tetrakismethylethylphosphinate, titanyl bisdiphenylphosphinate, and titanium tetrakisdiphenylphosphinate; nitrogen based flame retardants which includes triazine compounds such as melamine, melam, and melamine cyanurate, cyanuric acid compounds, isocyanuric acid compounds, triazole compounds, tetrazole compounds, diazo compounds, and urea; and silicon based flame retardants such as silicone compounds and silane compounds. Examples of the inorganic flame retardants include metal hydroxides such as aluminum hydroxide, magnesium hydroxide, zirconium hydroxide, barium hydroxide, and calcium hydroxide; metal oxides such as tin oxide, aluminum oxide, magnesium oxide, zirconium oxide, zinc oxide, molybdenum oxide, and nickel oxide; zinc carbonate, magnesium carbonate, barium carbonate, zinc borate, and hydrated glass. These flame retardants may be used in combination of two or more.

(Curing Agent)

Examples of the above curing agents include, but not limited thereto, amine-based curing agents and acid anhydride-based curing agents. Amine-based curing agents include, for instance, melamine resins such as methylated melamine resin, butylated melamine resin, and benzoguanamine resin; dicyandiamide, and 4,4′-diphenyldiaminosulfone. Acid anhydrides include, for example, aromatic acid anhydrides and aliphatic acid anhydrides. These curing agents may be used alone or in combination of two or more.

The content of the curing agent is preferably from 1 to 100 parts by mass, more preferably from 5 to 70 parts by mass, relative to 100 parts by mass of the epoxy resin (B).

(Curing Accelerator)

The above curing accelerator is used for the purpose of accelerating the reaction of the modified polypropylene-based resin (A) and the epoxy resin, and usable as the curing accelerator are tertiary amine-based curing accelerator, tertiary amine salt based curing accelerator, and imidazole based curing accelerator.

Examples of the tertiary amine-based curing accelerator include benzyldimethylamine, 2-(dimethylaminomethyl)phenol, 2,4,6-tris(dimethylaminomethyl)phenol, tetramethylguanidine, triethanolamine, N,N′-dimethylpiperadine, triethylenediamine, and 1,8-diazabicyclo[5.4.0] undecene.

Examples of the tertiary amine salt based curing accelerator include a formic acid salt, an acid salt, a p-toluenesulfonic acid salt, an o-phthalic acid salt, a phenol salt or a phenol novolac resin salt of 1,8-diazabicyclo[5.4.0] undecene, as well as a formic acid salt, an octylic acid salt, a p-toluenesulfonic acid salt, an o-phthalic acid salt, a phenol salt or a phenol novolac resin salt of 1,5-diazabicyclo[4.3.0] nonene.

Examples of the imidazole based curing accelerator include 2-methylimidazole, 2-undecylimidazole, 2-heptadecylimidazole, 1,2-dimethylimidazole, 2-methyl-4-ethylimidazole, 2-phenylimidazole, 2-phenyl-4-methylimidazole, 1-benzyl-2-methylimidazole, 1-benzyl-2-phenylimidazole, 2,4-diamino-6-[2′-methylimidazolyl-(1)]ethyl-s-triazine, 2,4-diamino-6-[2′-undecylimidazolyl-(1)]ethyl-s-triazine, 2,4-diamino-6-[2′-ethyl-4′-methylimidazolyl-(1)]ethyl-s-triazine, 2,4-diamino-6-[2′-methylimidazolyl-(1)]ethyl-s-triazine isocyanurate adduct, 2-phenylimidazole isocyanurate adduct, 2-phenyl-4,5-dihydroxymethylimidazole, and 2-phenyl-4-methyl-5-hydroxymethylimidazole. These curing accelerators may be used alone or in combination of two or more.

When the curing accelerator is contained in the adhesive composition, the content of the curing accelerator is preferably 1 to 15 parts by mass, more preferably 1 to 10 parts by mass, and still more preferably 2 to 5 parts by mass relative to 100 parts by mass of the epoxy resin (B). Excellent adhesiveness and thermal resistance can be exhibited so long as the content of the curing accelerator is in the aforementioned range.

(Coupling Agent)

Examples of the coupling agents include silane-based coupling agents such as vinyltrimethoxysilane, 3-glycydoxypropyltrimethoxysilane, p-styryltrimethoxysilane, 3-methacryloxypropylmethyldimethoxysilane, 3-acryloxypropyltrimethoxysilane, N-2-(aminoethyl)-3-aminopropylmethyldimethoxysilane, 3-ureidopropyltriethoxysilane, 3-mercaptopropylmethyldimethoxysilane, bis(triethoxysilylpropyl)tetrasulfide, 3-isocyanatopropyltriethoxysilane, and imidazolesilane; titanate-based coupling agents, aluminate-based coupling agents, and zirconium-based coupling agents. These may be used alone or in combination of two or more.

(Anti-Thermal Aging Agent)

Examples of the above anti-thermal aging agents include antioxidants which are exemplified by phenol-based antioxidants such as 2,6-di-tert-butyl-4-methylphenol, n-octadecyl-3-(3′,5′-di-tert-butyl-4′-hydroxyphenyl)propionate, tetrakis[methylene-3-(3,5-di-tert-butyl-4-hydroxyphenyl)propionate]methane, pentaerythritol tetrakis[3-(3,5-di-tert-butyl-4-hydroxyphenyl)propionate], and triethylene glycol bis[3-(3-tert-butyl-5-methyl-4-hydroxyphenyl)propionate]; sulfur-based antioxidants such as dilauryl 3,3′-thiodipropionate, and dimyristyl 3,3′-dithiopropionate; and phosphorus-based antioxidants such as tris(nonylphenyl) phosphite, and tris(2,4-di-tert-butylphenyl) phosphite. These may be used alone or in combination of two or more.

The adhesive composition of the present invention that contains the anti-thermal aging agent readily exhibits excellent dielectric properties even when the after-curing described later is carried out under high temperature conditions for a short time.

When the anti-thermal aging agent is contained in the adhesive composition, the content of the anti-thermal aging agent is preferably 0.5 to 5 parts by mass, and more preferably 1 to 3 parts by mass relative to 100 parts by mass of the solid content of the adhesive composition. The deterioration of the dielectric properties during heat curing at 180° C. can be suppressed so long as the content of the anti-thermal aging agent is in the aforementioned range.

(Inorganic Filler)

Examples of the inorganic fillers include powders of titanium oxide, aluminum oxide, zinc oxide, carbon black, silica, talc, copper, and silver. These may be used alone or in combination of two or more.

The above adhesive composition can be produced by mixing the modified polypropylene-based resin (A), the epoxy resin (B), the unmodified polypropylene-based resin (C), and other components. The mixing method is not specifically limited so long as a uniform adhesive composition is obtained. Since the adhesive composition is preferably used in the form a solution or a dispersion, a solvent such as an organic solvent is generally employed.

1.5. Organic Solvent

Examples of the organic solvent used in the present invention include: alcohol-based solvents such as methanol, ethanol, isopropyl alcohol, n-propyl alcohol, isobutyl alcohol, n-butyl alcohol, benzyl alcohol, ethylene glycol monomethyl ether, propylene glycol monomethyl ether, diethylene glycol monomethyl ether, and diacetone alcohol; ketone-based solvents such as acetone, methyl ethyl ketone, methyl isobutyl ketone, methyl amyl ketone, cyclohexanone, and isophorone; aromatic hydrocarbon-based solvents such as toluene, xylene, ethylbenzene, and mesitylene; ester-based solvents such as methyl acetate, ethyl acetate, ethylene glycol monomethyl ether acetate, and 3-methoxybutyl acetate; aliphatic hydrocarbon-based solvents such as hexane and heptane; and alicyclic hydrocarbon-based solvents such as cyclohexane and methylcyclohexane. These solvents may be used alone or in combination of two or more. When the adhesive composition contains an organic solvent so that the above modified polypropylene-based resin (A), the above epoxy resin (B), and the above unmodified polypropylene-based resin (C) are dissolved or dispersed in the organic solvent to form solutions or dispersions (resin varnish), the application to a base film and the formation of an adhesive layer can be smoothly carried out to readily obtain an adhesive layer at a desired thickness.

Among the above-exemplified solvents, the organic solvent used in the present invention preferably includes an alicyclic hydrocarbon-based solvent, i.e., methylcyclohexane and/or cyclohexane, and alcohol-based solvents. In such an embodiment, the content of the above alicyclic hydrocarbon relative to 100 parts by mass of the organic solvent is preferably 20 parts by mass or more and 90 parts by mass or less, and more preferably 40 parts by mass or more and 80 parts by mass or less.

In addition, the content of the above alcohol-based solvent relative to 100 parts by mass of the organic solvent is preferably 1 part by mass or more and 20 parts by mass or less, and more preferably 3 parts by mass or more and 10 parts by mass or less.

The content of the alicyclic hydrocarbon and/or alcohol-based solvent within the above ranges allows the adhesive composition to be excellent in storage stability at low temperatures.

In addition, the organic solvent used in the present invention preferably includes toluene, among the above-exemplified solvents. In such an embodiment, the content of toluene relative to 100 parts by mass of the adhesive composition is preferably 10 parts by mass or more and 60 parts by mass or less, and more preferably 20 parts by mass or more and 40 parts by mass or less. The content of toluene within the above ranges allows solubility of the epoxy resin (B) in the organic solvent to be improved.

When the adhesive composition includes an organic solvent, the solid content range is preferably 5 mass % or more and 50 mass % or less, more preferably 10 mass % or more and 40 mass % or less, from the viewpoint of, for example, workability including formation of the adhesive layer. If the solid content is 80 mass % or less, a solution with a favorable viscosity can be obtained to facilitate uniform coating.

2. The Laminate having an Adhesive Layer

The laminate having an adhesive layer according to the present invention comprises an adhesive layer formed of the above adhesive composition and a base film contacting at least one of the surfaces of the adhesive layer, and is further characterized in that the above adhesive layer is in B stage. Herein, the “adhesive layer is in B stage” refers to a semi-cured state in which a part of the adhesive composition starts curing, so that the curing of the adhesive composition further proceeds by heating or the like.

An embodiment of the laminate having an adhesive layer according to the present invention includes a coverlay film. A coverlay film comprises the aforementioned adhesive layer which is formed on at least one of the surfaces of a base film, and the adhesive layer cannot be easily peeled off from the base film.

When the laminate having an adhesive layer is a coverlay film, examples of the base film include a polyimide film, a polyether ether ketone film, a polyphenylene sulfide film, an aramid film, a polyethylene naphthalate film, and a liquid crystal polymer film. Preferred among them from the viewpoint of adhesiveness and dielectric properties are a polyimide film, a polyethylene naphthalate film, and a liquid crystal polymer film.

The aforementioned base films are commercially available; for instance, examples of the polyimide film include “KAPTON (registered trademark)” manufactured by Du Pont Toray Co., Ltd., “XENOMAX (registered trademark)” manufactured by Toyobo Co., Ltd., “UPILEX (registered trademark)-S” manufactured by Ube Industries, Ltd., and “APICAL (registered trademark)” manufactured by Kaneka Corporation. Examples of the polyethylene naphthalate film include “TEONEX (registered trademark)” manufactured by Teijin DuPont Films Japan Limited. Furthermore, examples of the liquid crystal polymer film include “VECSTAR (registered trademark)” manufactured by Kurary Co., Ltd, and “BIAC (registered trademark)” manufactured by Primatec Co., Ltd. The base film can also be obtained by making a film of desired thickness from the corresponding resin.

Methods for producing the coverlay film include, for example, a producing method in which a surface of a base film such as a polyimide film is coated with a resin varnish containing the above adhesive composition and a solvent to form a resin varnish layer, and then the solvent is removed from the resin varnish layer to obtain a coverlay film having an adhesive layer in B stage.

The drying temperature to remove the above solvent is preferably from 40 to 250° C., and more preferably from 70 to 170° C. The drying process is carried out by passing the laminate having the adhesive composition coated thereon through a furnace in which hot air drying, far infrared heating, high frequency induction heating or the like is carried out.

Furthermore, if necessary, a release film may be laminated onto the surface of the adhesive layer for preservation and the like. Examples of the release film include those known in the art, such as a polyethylene terephthalate film, a polyethylene film, a polypropylene film, a silicone-treated release paper, a polyolefin resin-coated paper, a polymethyl pentene (TPX) film, and a fluororesin film.

Another embodiment of the laminate having an adhesive layer includes a bonding sheet. The bonding sheet comprises the aforementioned adhesive layer formed on the surface of a base film wherein a release film is used as the base film. In another embodiment of the bonding sheet, the adhesive layer may be incorporated between two release films. The release film is peeled off when the bonding sheet is used. Examples of the release film are those mentioned above.

Such release films are commercially available, and examples thereof include “LUMIRROR (registered trademark)” manufactured by Toray Industries, Inc., “TOYOBO ESTER (registered trademark) film” manufactured by Toyobo Co., Ltd., “AFLEX (registered trademark)” manufactured by Asahi Glass Co., Ltd., and “OPULENT (registered trademark)” manufactured by Mitsui Chemicals Tohcello. Inc.

The bonding sheet can be produced by, for instance, coating the surface of a release film with a resin varnish containing the adhesive composition and a solvent, followed by drying in the same manner as in the case of the aforementioned coverlay film.

In order to make thinner the laminate having the adhesive layer, the thickness of the base film is preferably from 5 to 100 μm, more preferably from 5 to 50 μm, and still more preferably from 5 to 30 μm.

The thickness of the adhesive layer in B stage is preferably from 5 to 100 μm, more preferably from 10 to 70 μm, and still more preferably 10 to 50 μm.

Although the thicknesses of the above base film and adhesive layer are selected depending on usage, the base film tend to be thinner to improve dielectric properties. In general, warpage of the laminate having an adhesive layer tends to occur and impairs workability with decreasing the thickness of the base film and increasing the thickness of the adhesive layer. However, the laminate having an adhesive layer according to the present invention hardly causes the warpage of the laminate even when the base film is thin and the adhesive layer is thick. In the laminate having an adhesive layer according to the present invention, the ratio of the thickness of the adhesive layer (A) to the thickness of the base film (B), i.e., (A/B), is preferably not less than 1 and not more than 10, and more preferably not less than 1 and not more than 5. Further, it is preferred that the thickness of the adhesive layer is larger than the thickness of the base film.

It is preferred that the warpage of the laminate having an adhesive layer is as small as possible because the warpage affects workability in the production process of FPC-related products. More specifically, when a square-shaped laminate having an adhesive layer is placed on a horizontal surface with the adhesive layer facing up, the ratio (H/L) wherein H is an elevation of an edge of the laminate and L is a side length of the laminate is preferably less than 0.05. The ratio is more preferably less than 0.04, and still more preferably less than 0.03. When the ratio (H/L) is less than 0.05, a laminate with excellent workability can be obtained because the warpage or curling of the laminate can be suppressed.

Additionally, the lower limit of the H/L is 0, i.e., when H is 0.

The laminate having the adhesive layer preferably yields a dielectric constant (ε) lower than 3.0 and a dielectric loss tangent (tan δ) lower than 0.01 when measured at a frequency of 1 GHz after the adhesive layer of the laminate is cured. More preferably, the dielectric constant is 2.7 or lower, and the dielectric loss tangent is 0.003 or lower. The above laminate can be favorably used in FPC-related products which must meet strict dielectric property requirements, i.e., cope with higher signal speeds and higher signal frequencies in recent year so long as the laminate yields a dielectric constant lower than 3.0 and a dielectric loss tangent lower than 0.01. Since the dielectric constant and the dielectric loss tangent can be adjusted by the type and content of the adhesive component or the type of the base film and the like, various types of laminates can be designed depending on the usage.

Furthermore, it is preferred that the laminate having the adhesive layer yields a dielectric constant (ε) of 2.0 or more and a dielectric loss tangent (tan δ) of 0 or more as measured at a frequency of 1 GHz after the adhesive layer of the laminate is cured.

### 3. Flexible Copper Clad Laminate

The flexible copper clad laminate according to the present invention is characterized in that a base film and a copper foil are bonded to each other using the aforementioned laminate having an adhesive layer. That is, the flexible copper clad laminate according to the present invention comprises a base film, an adhesive layer, and a copper foil in this order. The adhesive layer and the copper foil may be formed on both surfaces of the base film. Since the adhesive composition of the present invention is excellent in adhesion to articles containing copper, the flexible copper clad laminate according to the present invention is provided as an integrated product excellent in stability.

The method for producing the flexible copper clad laminate according to the present invention includes, for instance, a method in which the surface of the adhesive layer of the laminate is brought in contact with the copper foil, hot lamination is carried out at from 80 to 150° C., and then the adhesive layer is cured by after-curing. The after-curing conditions can be, for example, at from 100 to 200° C. for from 30 minutes to 4 hours. There is no particular limitation on the copper foil, and usable are electrolytic copper foil, rolled copper foil, and the like.

### 4. Flexible Flat Cable (FFC)

The flexible flat cable according to the present invention is characterized in that a base film and a copper wiring are bonded to each other using the aforementioned laminate having an adhesive layer. That is, the flexible flat cable according to the present invention comprises a base film, an adhesive layer, and a copper wiring in this order. The adhesive layer and the copper wiring may be formed on both surfaces of the base film. Since the adhesive composition of the present invention is excellent in adhesion to articles containing copper, the flexible flat cable according to the present invention is provided as an integrated product excellent in stability.

The method for producing the flexible flat cable according to the present invention includes, for instance, a method in which the adhesive layer of the laminate is brought in contact with the copper wiring, hot lamination is carried out at from 80 to 150° C., and then the adhesive layer is cured by after-curing. The after-curing condition can be, for example, at from 100 to 200° C. for from 30 minutes to 4 hours. There is no particular limitation on the shape of the copper wiring, so the shape and the like can be properly selected as desired.

### EXAMPLES

The present invention is explained in further detail by way of Examples below, but the present invention is not limited thereto. In the explanation below, parts and % are on mass basis unless otherwise stated.

### 1. Evaluation Method

### (1) Weight Average Molecular Weight

GPC measurement was carried out under the following conditions to determine Mw of the modified polypropylene-based resin (A).

Mw was determined by converting the retention time measured by GPC based on standard polystyrene retention time.

Instrument: Alliance2695 (manufactured by Waters)

Column: 2 columns of TSK gel SuperMultiporeHZ-H
2 columns of TSK gel SuperHZ2500 (manufactured by Tosoh Corporation)

Column temperature: 40° C.

Carrier solvent: Tetrahydrofuran 0.35 ml/min

Detector: RI (Differential Refractive Index Detector)

### (2) Acid Value

One (1) gram of the modified polypropylene-based resin (A) was dissolved in 30 ml of toluene, and an automatic titrator “AT-510” (manufactured by KYOTO ELECTRONICS MANUFACTURING CO., LTD.) to which a burette “APB-510-20B” (manufactured by the same) was connected was used. Potentiometric titration was carried out using 0.01 mol/L benzyl alcoholic KOH solution as a titrant, and an amount in milligrams of KOH per 1 g of resin was calculated.

### (3) Peel Adhesion Strength

A 25-μm thick polyimide film was prepared, and the adhesive compositions of Examples 1 to 28 and of Comparative Examples 1 to 13 having compositions described in Table 1 were each applied by roll-coating to one of the surfaces of the film. The coated film was then allowed to stand still in an oven, and was dried at 90° C. for 3 minutes to form a 25-μm thick adhesive layer in B stage to obtain a coverlay film (a laminate having the adhesive layer each of Examples 1 to 28 and Comparative Examples 1 to 13). Then, a 35-μm thick rolled copper foil was brought into surface contact with the surface of the adhesive layer of the coverlay film, and the resultant was subjected to lamination under a temperature of 120° C., a pressure of 0.4 MPa, and a speed of 0.5 m/minute. Then, the resulting laminate (polyimide film/adhesive layer/copper foil) was subjected to hot pressing at a temperature of 180° C. and a pressure of 3 MPa for 30 minutes to obtain a flexible copper clad laminate A. The thus-obtained flexible copper clad laminate A was cut into a specified size to prepare an adhesion test piece.

In accordance with JIS C 6481 “Test methods of copper-clad laminates for printed wiring boards”, adhesiveness was evaluated by measuring a 180° peel adhesion strength (N/mm) when the copper foil of each adhesion test piece was peeled off from the polyimide film under a temperature of 23° C. and a tensile speed of 50 mm/minute. The width of the adhesion test piece at the time of measurement was 10 mm.

### (4) Warpage

A 25-μm thick polyimide film (200 mm length×200 mm width) was prepared, and the adhesive compositions of Examples 1 to 28 and of Comparative Examples 1 to 13 having compositions described in Table 1 were each applied by roll-coating to one of the surfaces of the film. The coated film was then allowed to stand still in an oven, and was dried at 90° C. for 3 minutes to form a 25-μm thick adhesive layer in B stage to obtain a coverlay film (a 50-μm thick laminate having the adhesive layer each of Examples 1 to 28 and Comparative Examples 1 to 13). The resulting coverlay film was placed on a horizontal plane with the adhesive layer facing upward, and the elevation in the vertical direction was measured at each of the four corners. The thus-measured elevations at the four corners were averaged, and the ratio of the average elevation (H) to the side length (L) of the laminate, i.e., H/L, was obtained and used to evaluate the warpage.

### <Evaluation Criteria>

⊚: H/L is lower than 0.020

◯: H/L is 0.030 or more and lower than 0.05

×: H/L is 0.10 or more

### (5) Solder Heat Resistance

The test was conducted in accordance with JIS C 6481 “Test methods of copper-clad laminates for printed wiring boards”. The adhesion test pieces were each cut into 20-mm square, and were subjected to heat treatment at 120° C. for 30 minutes. Then, with the polyimide film facing up, the adhesion test pieces were floated on a solder bath for 60 seconds at 260° C. to observe foaming on the surface of the adhesion test pieces.

<Evaluation Criteria>

◯: Without blister

×: With blister

### (6) Dielectric Properties (Dielectric Constant and Dielectric Loss Tangent)

### (a) Cured Body of the Adhesive

A 38-μm thick polyethylene terephthalate release film was prepared, and one of the surfaces thereof was roll-coated with an adhesive composition each of Examples 1 to 28 and Comparative Examples 1 to 13 having compositions described in Table 1. The coated film was then allowed to stand still in an oven, and was dried at 90° C. for 3 minutes to form a 50-μm thick coated film (adhesive layer) to obtain a bonding sheet. This bonding sheet was then allowed to stand still in an oven, and was treated with heat at 150° C. for 60 minutes or 180° C. for 30 minutes. Subsequently, the above release film was removed to prepare a test piece of 150 mm×120 mm in size. The dielectric constant (ε) and the dielectric loss tangent (tan δ) were measured using a network analyzer 85071E-300 (manufactured by Agilent Technologies, Inc.) in accordance with the split post dielectric resonator (SPDR) method, at a temperature of 23° C. and at a frequency of 1 GHz.

(b) Laminate having Adhesive Layer

A 25-μm thick polyimide film was prepared, and one of the surfaces thereof was roll-coated with an adhesive composition each of Examples 1 to 28 and Comparative Examples 1 to 13 having compositions described in Table 1. The coated film was then allowed to stand still in an oven, and was dried at 90° C. for 3 minutes to form a 25-μm thick adhesive layer in B stage to obtain a coverlay film (a 50-μm thick laminate having the adhesive layer each of Examples 1 to 28 and Comparative Examples 1 to 13). The resulting coverlay film was then allowed to stand still in an oven, and was heated and cured at 150° C. for 60 minutes to obtain a test piece of 120 mm×100 mm in size.

The dielectric constant (ε) and the dielectric loss tangent (tan δ) of the laminate having an adhesive layer were measured using a network analyzer 85071E-300 (manufactured by Agilent Technologies, Inc.) in accordance with the split post dielectric resonator (SPDR) method, at a temperature of 23° C. and at a frequency of 1 GHz.

### (7) Storage Stability of the Adhesive Composition

Each of the adhesive compositions of Examples 1 to 28 and Comparative Examples 1 to 13 having the compositions described in Table 1 was placed in a glass bottle, sealed, and stored at 5° C. for a predetermined time, and crystallinity of the compositions was observed. After storage for a predetermined time, the point where the fluidity of the adhesive composition disappeared was regarded as crystallization of the resin (poor storage stability), and evaluation was carried out.

### <Evaluation Criteria>

⊚: 1 month or more

◯: 2 weeks or more and less than 1 month

Δ: 1 week or more and less than 2 weeks

×: less than 1 week

(8) Storage Stability of the Laminate having an Adhesive Layer

A 25-μm thick polyimide film was prepared, and one of the surfaces thereof was roll-coated with an adhesive composition each of Examples 1 to 28 and Comparative Examples 1 to 13 having compositions described in Table 1. The coated film was then allowed to stand still in an oven, and was dried at 90° C. for 3 minutes to form a 25-μm thick adhesive layer in B stage to obtain a coverlay film (a 50-μm thick laminate having the adhesive layer each of Examples 1 to 28 and Comparative Examples 1 to 13). The prepared coverlay film was stored at 23° C. for a predetermined duration of time, and the coverlay film after storage was subjected to hot pressing with a copper single-sided board (L/S=50 μm/50 μm, having copper thickness of 18 μm) at a temperature of 180° C. and a pressure of 3 MPa for 3 minutes to evaluate a filling property of the resin. The storage period of time at which the resin no longer fills in the board was taken for evaluation.

### <Evaluation Criteria>

◯: 2 months or longer

Δ: 1 week or longer and less than 1 month

### 2. Production of Modified Polypropylene-Based Resin (A)

Modified polypropylene-based resins al to a3 were produced as the modified polypropylene-based resin (A) by the method described below.

### (1) Modified Polypropylene-Based Resin a1

One hundred (100) parts by mass of a propylene-butene random copolymer composed of 65 mass % of propylene units and 35 mass % of 1-butene units and produced using a metallocene catalyst as a polymerization catalyst, 1 part by mass of maleic anhydride, 0.3 part by mass of lauryl methacrylate, and 0.4 part by mass of di-t-butylperoxide were kneaded and reacted in a twin-screw extruder in which the maximum temperature in the cylinder portion thereof was set to 170° C. Then, the remaining unreacted substances were removed by degassing in vacuo in the extruder to produce a modified polypropylene-based resin a1. The modified polypropylene-based resin al had a weight average molecular weight of 70,000, an acid value of 10 mg KOH/g, and a propylene/butene mass ratio of 65/35.

### (2) Modified Polypropylene-Based Resin a2

One hundred (100) parts by mass of a propylene-butene random copolymer composed of 60 mass % of propylene units and 40 mass % of butene units and produced using a metallocene catalyst as a polymerization catalyst, 1 part by mass of maleic anhydride, 0.3 part by mass of lauryl methacrylate, and 0.4 part by mass of di-t-butylperoxide were kneaded and reacted in a twin-screw extruder in which the maximum temperature in the cylinder portion thereof was set to 170° C. Then, the remaining unreacted substances were removed by degassing in vacuo in the extruder to produce a modified polypropylene-based resin a2. The modified polypropylene-based resin a2 had a weight average molecular weight of 60,000, an acid value of 10 mg KOH/g, and a propylene/butene mass ratio of 60/40.

### (3) Modified Polypropylene-Based Resin a3

One hundred (100) parts by mass of a propylene-butene random copolymer composed of 80 mass % of propylene units and 20 mass % of butene units and produced using a metallocene catalyst as a polymerization catalyst, 1 part by mass of maleic anhydride, 0.3 part by mass of lauryl methacrylate, and 0.4 part by mass of di-t-butylperoxide were kneaded and reacted in a twin-screw extruder in which the maximum temperature in the cylinder portion thereof was set to 170° C. Then, the remaining unreacted substances were removed by degassing in vacuo in the extruder to produce a modified polypropylene-based resin a3. The modified polypropylene-based resin a3 had a weight average molecular weight of 60,000, an acid value of 10 mg KOH/g, and a propylene/butene mass ratio of 80/20.

### 3. Production of Unmodified Polypropylene-Based Resin

### (1) Unmodified Polypropylene-Based Resin c1

An unmodified polypropylene-based resin c1 was obtained, which was produced by reacting 65 mass % of propylene units and 35 mass % of butene units using a metallocene catalyst as a polymerization catalyst. The unmodified polypropylene-based resin cl had a weight average molecular weight of 150,000, and a propylene/butene mass ratio of 65/35.

### (2) Unmodified Polypropylene-Based Resin c2

An unmodified polypropylene-based resin c2 was obtained, which was produced by reacting 60 mass % of propylene units and 40 mass % of butene units using a metallocene catalyst as a polymerization catalyst. The unmodified polypropylene-based resin c2 had a weight average molecular weight of 150,000, and a propylene/butene mass ratio of 60/40.

### (3) Unmodified Polypropylene-Based Resin c3

An unmodified polypropylene-based resin c3 was obtained, which was produced by reacting 75 mass % of propylene units and 25 mass % of butene units using a metallocene catalyst as a polymerization catalyst. The unmodified polypropylene-based resin c3 had a weight average molecular weight of 150,000, and a propylene/butene mass ratio of 75/25.

### 4. Raw Materials of the Adhesive Composition

### 4-1. Epoxy Resin (B)

### (1) Epoxy Resin b1

An epoxy resin having a dicyclopentadiene structure, “EPICLON HP-7200” (trade name) manufactured by DIC Corporation, was used.

### 4-2. Additives

### (1) Curing Accelerator

An imidazole-based curing accelerator “CURESOL C11-Z” (trade name), manufactured by Shikoku Chemicals Corporation was used.

### (2) Antioxidant

A hindered phenol-based antioxidant “AO-60” (trade name), manufactured by ADEKA Corporation was used.

### 4-3. Organic Solvent

Methylcyclohexane, cyclohexane, toluene, isopropyl alcohol, benzyl alcohol, and methyl ethyl ketone were used.

### 5. Production of an Adhesive Composition

The above raw materials were put into a 1000-ml flask equipped with a stirrer in the proportion shown in Table 1, and were dissolved under stirring for 6 hours at room temperature to prepare an adhesive composition, and evaluation thereof was carried out. The results are given in Table 1 and Table 2. The adhesive compositions of Comparative Examples 4, 5, and 13 were not subjected to the above evaluation, because resin components were not dissolved in the solvent.

6. Production and Evaluation of the Laminate having an Adhesive Layer

Laminates having adhesive layer were each produced using the above adhesive compositions as described above in explanation of each evaluation method, and were subjected to evaluation. The results are given in Table 1 and Table 2.

TABLE 1

Examples

| | | | 1 | 2 | 3 | 4 | 5 | 6 | 7 | 8 | 9 | 10 |
|---|---|---|---|---|---|---|---|---|---|---|---|---|
| Adhesive | <Resin | Acid-modified polypropylene-based | 10 | 10 | 5 | 10 | 10 | 10 | 10 | 10 | | 10 |
| composition | components> | resin a1 | | | | | | | | | | |
| (parts by mass) | | Acid-modified polypropylene-based | | | | | | | | | 10 | |
| | | resin a2 | | | | | | | | | | |
| | | Acid-modified polypropylene-based | | | | | | | | | | |
| | | resin a3 | | | | | | | | | | |
| | | Unmodified polypropylene-based | 5 | 10 | 10 | 10 | 10 | 10 | 10 | 10 | 10 | |
| | | resin c1 | | | | | | | | | | |
| | | Unmodified polypropylene-based | | | | | | | | | | 10 |
| | | resin c2 | | | | | | | | | | |
| | | Unmodified polypropylene-based | | | | | | | | | | |
| | | resin c3 | | | | | | | | | | |
| | | Epoxy resin b1 | 0.5 | 0.5 | 0.25 | 0.5 | 0.5 | 0.5 | 0.5 | 0.5 | 0.5 | 0.5 |
| | | Anti-thermal aging agent | 0.2 | 0.2 | 0.2 | 0.2 | 0.2 | 0.2 | 0.2 | 0.2 | 0.2 | 0.2 |
| | | Curing accelerator | 0.02 | 0.02 | 0.02 | 0.02 | 0.02 | 0.02 | 0.02 | 0.02 | 0.02 | 0.02 |
| | <Solvents> | Methylcyclohexane | 40 | 40 | 40 | 60 | 40 | 20 | 20 | 40 | 40 | 40 |
| | | Cyclohexane | | | | | 20 | | 20 | | | |
| | | Toluene | 40 | 40 | 40 | 20 | 20 | 60 | 40 | 40 | 40 | 40 |
| | | Methyl ethyl ketone | | | | | | | | | | |
| | | Isopropyl alcohol | 5 | 5 | 5 | 5 | 5 | 5 | 5 | | 5 | 5 |
| | | Benzyl alcohol | | | | | | | | 5 | | |
| <Evaluation | Dielectric | Dielectric constant (ε) of cured body | 2.17 | 2.15 | 2.13 | 2.15 | 2.15 | 2.15 | 2.15 | 2.15 | 2.16 | 2.16 |
| results> | properties | of resin after heat curing at 150° C. for | | | | | | | | | | |
| | | 60 minutes | | | | | | | | | | |
| | | Dielectric loss tangent (tan δ) of cured | 0.0008 | 0.0007 | 0.0006 | 0.0007 | 0.0007 | 0.0007 | 0.0007 | 0.0007 | 0.0008 | 0.0008 |
| | | body of resin after heat curing at | | | | | | | | | | |
| | | 150° C. for 60 minutes | | | | | | | | | | |
| | | Dielectric constant (ε) of cured body | 2.17 | 2.15 | 2.13 | 2.15 | 2.15 | 2.15 | 2.15 | 2.15 | 2.16 | 2.16 |
| | | of resin after heat curing at 180° C. for | | | | | | | | | | |
| | | 30 minutes | | | | | | | | | | |
| | | Dielectric loss tangent (tan δ) of cured | 0.0008 | 0.0007 | 0.0006 | 0.0007 | 0.0007 | 0.0007 | 0.0007 | 0.0007 | 0.0008 | 0.0008 |
| | | body of resin after heat curing at | | | | | | | | | | |
| | | 180° C. for 30 minutes | | | | | | | | | | |
| | | Dielectric constant (ε) of coverlay | 2.70 | 2.68 | 2.65 | 2.68 | 2.68 | 2.68 | 2.68 | 2.68 | 2.68 | 2.68 |
| | | film after heat curing at 150° C. for 60 | | | | | | | | | | |
| | | minutes | | | | | | | | | | |
| | | Dielectric loss tangent (tan δ) of | 0.0030 | 0.0028 | 0.0027 | 0.0028 | 0.0028 | 0.0028 | 0.0028 | 0.0028 | 0.0030 | 0.0030 |
| | | coverlay film after heat curing at | | | | | | | | | | |
| | | 150° C. for 60 minutes | | | | | | | | | | |
| | Adhesiveness | Peel adhesion strength of flexible | 17 | 16 | 16 | 16 | 16 | 16 | 16 | 16 | 16 | 16 |
| | | copper clad laminate (N/mm) | | | | | | | | | | |

| | | | | | | | | | | |
|---|---|---|---|---|---|---|---|---|---|---|
| Solder heat resistance of flexible copper clad | ◯ | ◯ | ◯ | ◯ | ◯ | ◯ | ◯ | ◯ | ◯ | ◯ |
| laminate (° C.) | | | | | | | | | | |
| Storage stability of adhesive composition at low | ◯ | ⊚ | ⊚ | ⊚ | ⊚ | ◯ | ◯ | ◯ | ⊚ | ⊚ |
| temperatures | | | | | | | | | | |
| Storage stability of coverlay film | ◯ | ◯ | ◯ | ◯ | ◯ | ◯ | ◯ | ◯ | ◯ | ◯ |
| Warpage of coverlay film | ⊚ | ⊚ | ⊚ | ⊚ | ⊚ | ⊚ | ⊚ | ⊚ | ⊚ | ⊚ |

| | | | Examples | | | | | | | | | |
|---|---|---|---|---|---|---|---|---|---|---|---|---|
| | | | 11 | 12 | 13 | 14 | 15 | 16 | 17 | 18 | 19 | 20 |
| Adhesive | <Resin | Acid-modified polypropylene-based | | | 10 | 10 | 10 | 10 | 10 | | | 3 |
| composition | components> | resin a1 | | | | | | | | | | |
| (parts by mass) | | Acid-modified polypropylene-based | 10 | 10 | | | | | | | | |
| | | resin a2 | | | | | | | | | | |
| | | Acid-modified polypropylene-based | | | | | | | | 10 | 10 | |
| | | resin a3 | | | | | | | | | | |
| | | Unmodified polypropylene-based | | | 10 | 10 | 10 | 10 | | | 5 | 17 |
| | | resin c1 | | | | | | | | | | |
| | | Unmodified polypropylene-based | 10 | 10 | | | | | | | | |
| | | resin c2 | | | | | | | | | | |
| | | Unmodified polypropylene-based | | | | | | | 10 | 10 | | |
| | | resin c3 | | | | | | | | | | |
| | | Epoxy resin b1 | 0.5 | 0.5 | 0.5 | 0.5 | 0.5 | 0.5 | 0.5 | 0.5 | 0.5 | 0.15 |
| | | Anti-thermal aging agent | 0.2 | | 0.2 | 0.2 | 0.2 | 0.2 | 0.2 | 0.2 | 0.2 | 0.2 |
| | | Curing accelerator | 0.02 | 0.02 | 0.02 | 0.02 | 0.02 | 0.02 | 0.02 | 0.02 | 0.02 | 0.02 |
| | <Solvents> | Methylcyclohexane | 40 | 40 | 40 | 35 | 10 | 43 | 40 | 40 | 40 | 40 |
| | | Cyclohexane | | | | | | | | | | |
| | | Toluene | 40 | 40 | 40 | 30 | 70 | 42 | 40 | 40 | 40 | 40 |
| | | Methyl ethyl ketone | | | 5 | | | | | | | |
| | | Isopropyl alcohol | 5 | 5 | | 20 | 5 | | 5 | 5 | 5 | 5 |
| | | Benzyl alcohol | | | | | | | | | | |
| <Evaluation | Dielectric | Dielectric constant (ε) of cured body | 2.18 | 2.18 | 2.15 | 2.15 | 2.15 | 2.15 | 2.17 | 2.16 | 2.18 | 2.13 |
| results> | properties | of resin after heat curing at 150° C. for | | | | | | | | | | |
| | | 60 minutes | | | | | | | | | | |
| | | Dielectric loss tangent (tan δ) of cured | 0.0008 | 0.0008 | 0.0007 | 0.0007 | 0.0007 | 0.0007 | 0.0008 | 0.0007 | 0.0007 | 0.0006 |
| | | body of resin after heat curing at | | | | | | | | | | |
| | | 150° C. for 60 minutes | | | | | | | | | | |
| | | Dielectric constant (ε) of cured body | 2.18 | 2.28 | 2.15 | 2.15 | 2.15 | 2.15 | 2.17 | 2.16 | 2.18 | 2.13 |
| | | of resin after heat curing at 180° C. for | | | | | | | | | | |
| | | 30 minutes | | | | | | | | | | |
| | | Dielectric loss tangent (tan δ) of cured | 0.0008 | 0.0030 | 0.0007 | 0.0007 | 0.0007 | 0.0007 | 0.0008 | 0.0007 | 0.0007 | 0.0006 |
| | | body of resin after heat curing at | | | | | | | | | | |
| | | 180° C. for 30 minutes | | | | | | | | | | |
| | | Dielectric constant (ε) of coverlay | 2.70 | 2.70 | 2.68 | 2.68 | 2.68 | 2.68 | 2.70 | 2.68 | 2.70 | 2.63 |
| | | film after heat curing at 150° C. for 60 | | | | | | | | | | |
| | | minutes | | | | | | | | | | |
| | | Dielectric loss tangent (tan δ) of | 0.0030 | 0.0030 | 0.0028 | 0.0028 | 0.0028 | 0.0028 | 0.0030 | 0.0028 | 0.0028 | 0.0027 |
| | | coverlay film after heat curing at | | | | | | | | | | |
| | | 150° C. for 60 minutes | | | | | | | | | | |
| | Adhesiveness | Peel adhesion strength of flexible | 16 | 16 | 16 | 16 | 16 | 16 | 16 | 16 | 16 | 15 |
| | | copper clad laminate (N/mm) | | | | | | | | | | |

| | | | | | | | | | | |
|---|---|---|---|---|---|---|---|---|---|---|
| Solder heat resistance of flexible copper clad | ◯ | ◯ | ◯ | ◯ | ◯ | ◯ | ◯ | ◯ | ◯ | ◯ |
| laminate (° C.) | | | | | | | | | | |
| Storage stability of adhesive composition at low | ⊚ | ⊚ | Δ | Δ | Δ | Δ | Δ | X | X | ⊚ |
| temperatures | | | | | | | | | | |
| Storage stability of coverlay film | ◯ | ◯ | ◯ | ◯ | ◯ | ◯ | ◯ | ◯ | ◯ | ◯ |
| Warpage of coverlay film | ⊚ | ⊚ | ⊚ | ⊚ | ⊚ | ⊚ | ⊚ | ⊚ | ⊚ | ⊚ |

TABLE 2

| | | | Examples | | | | | | | | Comparative Examples | | |
|---|---|---|---|---|---|---|---|---|---|---|---|---|---|
| | | | 21 | 22 | 23 | 24 | 25 | 26 | 27 | 28 | 1 | 2 | 3 |
| Adhesive | <Resin | Acid-modified | 17 | 19 | 10 | 10 | 10 | 10 | 10 | 10 | 20 | | 10 |
| composition | components> | polypropylene-based resin a1 | | | | | | | | | | | |
| (parts by mass) | | Acid-modified | | | | | | | | | | | |
| | | polypropylene-based resin a2 | | | | | | | | | | | |
| | | Acid-modified | | | | | | | | | | | |
| | | polypropylene-based resin a3 | | | | | | | | | | | |
| | | Unmodified | 3 | 1 | 5 | 5 | 5 | 5 | 5 | 5 | | 20 | 10 |
| | | polypropylene-based resin c1 | | | | | | | | | | | |
| | | Unmodified | | | | | | | | | | | |
| | | polypropylene-based resin c2 | | | | | | | | | | | |
| | | Unmodified | | | | | | | | | | | |
| | | polypropylene-based resin c3 | | | | | | | | | | | |
| | | Epoxy resin b1 | 0.85 | 0.95 | 0.5 | 0.5 | 0.5 | 0.5 | 0.5 | 0.5 | 1 | 1 | |
| | | Anti-thermal aging agent | 0.2 | 0.2 | 0.2 | 0.2 | 0.2 | 0.2 | 0.2 | 0.2 | 0.2 | 0.2 | 0.2 |
| | | Curing accelerator | 0.02 | 0.02 | 0.02 | 0.02 | 0.02 | 0.02 | 0.02 | 0.02 | 0.04 | 0.04 | 0.02 |
| | <Solvents> | Methylcyclohexane | 40 | 40 | 20 | 40 | 70 | 20 | 40 | 70 | 40 | 40 | 40 |
| | | Cyclohexane | | | | | | | | | | | |
| | | Toluene | 40 | 40 | 50 | 30 | 5 | 60 | 40 | 10 | 40 | 40 | 40 |
| | | Methyl ethyl ketone | | | | | | | | | | | |
| | | Isopropyl alcohol | 5 | 5 | 15 | 15 | 10 | 2 | 2 | 2 | 5 | 5 | 5 |
| | | Benzyl alcohol | | | | | | | | | | | |
| <Evaluation | Dielectric | Dielectric constant (ε) of | 2.18 | 2.18 | 2.17 | 2.17 | 2.17 | 2.17 | 2.17 | 2.17 | 2.22 | 2.20 | 2.12 |
| results> | properties | cured body of resin after heat | | | | | | | | | | | |
| | | curing at 150° C. for 60 minutes | | | | | | | | | | | |
| | | Dielectric loss tangent (tan δ) | 0.0009 | 0.0009 | 0.0008 | 0.0008 | 0.0008 | 0.0008 | 0.0008 | 0.0008 | 0.0012 | 0.0012 | 0.0006 |
| | | of cured body of resin after | | | | | | | | | | | |
| | | heat curing at 150° C. for 60 | | | | | | | | | | | |
| | | minutes | | | | | | | | | | | |
| | | Dielectric constant (ε) of | 2.18 | 2.18 | 2.17 | 2.17 | 2.17 | 2.17 | 2.17 | 2.17 | 2.22 | 2.20 | 2.12 |
| | | cured body of resin after heat | | | | | | | | | | | |
| | | curing at 180° C. for 30 minutes | | | | | | | | | | | |
| | | Dielectric loss tangent (tan δ) | 0.0009 | 0.0009 | 0.0008 | 0.0008 | 0.0008 | 0.0008 | 0.0008 | 0.0008 | 0.0012 | 0.0012 | 0.0006 |
| | | of cured body of resin after | | | | | | | | | | | |
| | | heat curing at 180° C. for 30 | | | | | | | | | | | |
| | | minutes | | | | | | | | | | | |
| | | Dielectric constant (ε) of | 2.70 | 2.70 | 2.70 | 2.70 | 2.70 | 2.70 | 2.70 | 2.70 | 2.85 | 2.83 | 2.65 |
| | | coverlay film after heat curing | | | | | | | | | | | |
| | | at 150° C. for 60 minutes | | | | | | | | | | | |
| | | Dielectric loss tangent (tan δ) | 0.0030 | 0.0030 | 0.0030 | 0.0030 | 0.003 | 0.003 | 0.003 | 0.003 | 0.0035 | 0.0035 | 0.0027 |
| | | of coverlay film after heat | | | | | | | | | | | |
| | | curing at 150° C. for 60 minutes | | | | | | | | | | | |
| | Adhesiveness | Peel adhesion strength of | 17 | 17 | 17 | 17 | 17 | 17 | 17 | 17 | 17 | 10 | 10 |
| | | flexible copper clad laminate | | | | | | | | | | | |
| | | (N/mm) | | | | | | | | | | | |

| | | | | | | | | | | | |
|---|---|---|---|---|---|---|---|---|---|---|---|
| Solder heat resistance of flexible copper clad | ◯ | ◯ | ◯ | ◯ | ◯ | ◯ | ◯ | ◯ | ◯ | X | X |
| laminate (° C.) | | | | | | | | | | | |
| Storage stability of adhesive composition at | ⊚ | ⊚ | ◯ | ◯ | ⊚ | ◯ | ⊚ | ⊚ | ⊚ | ⊚ | ⊚ |
| low temperatures | | | | | | | | | | | |
| Storage stability of coverlay film | ◯ | ◯ | ◯ | ◯ | ◯ | ◯ | ◯ | ◯ | ◯ | ◯ | ◯ |
| Warpage of coverlay film | ⊚ | ⊚ | ⊚ | ⊚ | ⊚ | ⊚ | ⊚ | ⊚ | ⊚ | ⊚ | ⊚ |

| | | | Comparative Examples | | | | | | | | | |
|---|---|---|---|---|---|---|---|---|---|---|---|---|
| | | | 4 | 5 | 6 | 7 | 8 | 9 | 10 | 11 | 12 | 13 |
| Adhesive | <Resin | Acid-modified | | | 1 | 1 | 20 | 20 | 20 | 20 | 20 | 20 |
| composition | components> | polypropylene-based resin a1 | | | | | | | | | | |
| (parts by mass) | | Acid-modified | 20 | | | | | | | | | |
| | | polypropylene-based resin a2 | | | | | | | | | | |
| | | Acid-modified | | | | | | | | | | |
| | | polypropylene-based resin a3 | | | | | | | | | | |
| | | Unmodified | | | 19 | 17 | 0.1 | | | | | |
| | | polypropylene-based resin c1 | | | | | | | | | | |
| | | Unmodified | | | | | | | | | | |
| | | polypropylene-based resin c2 | | | | | | | | | | |
| | | Unmodified | | 20 | | | | | | | | |
| | | polypropylene-based resin c3 | | | | | | | | | | |
| | | Epoxy resin b1 | 0.5 | 0.5 | 0.05 | 2.5 | 1 | 1 | 1 | 1 | 1 | 1 |
| | | Anti-thermal aging agent | 0.2 | 0.2 | 0.2 | 0.2 | 0.2 | 0.2 | 0.2 | 0.2 | 0.2 | 0.2 |
| | | Curing accelerator | 0.02 | | 0.04 | 0.04 | 0.04 | 0.04 | 0.04 | 0.04 | 0.04 | 0.04 |
| | <Solvents> | Methylcyclohexane | 85 | 80 | 40 | 40 | 40 | 5 | 15 | 15 | 5 | 80 |
| | | Cyclohexane | | | | | | | | | | |
| | | Toluene | | | 40 | 40 | 40 | 75 | 65 | 45 | 55 | |
| | | Methyl ethyl ketone | | | | | | | | | | |
| | | Isopropyl alcohol | | 5 | 5 | 5 | 5 | 5 | 5 | 25 | 25 | 5 |
| | | Benzyl alcohol | | | | | | | | | | |
| <Evaluation | Dielectric | Dielectric constant (ε) of | Not | Not | 2.12 | 2.27 | 2.22 | 2.22 | 2.22 | 2.22 | 2.22 | Not |
| results> | properties | cured body of resin after heat | dissolved | dissolved | | | | | | | | dissolved |
| | | curing at 150° C. for 60 minutes | | | | | | | | | | |
| | | Dielectric loss tangent (tan δ) | | | 0.0006 | 0.0015 | 0.0012 | 0.0012 | 0.0012 | 0.0012 | 0.0012 | |
| | | of cured body of resin after | | | | | | | | | | |
| | | heat curing at 150° C. for 60 | | | | | | | | | | |
| | | minutes | | | | | | | | | | |
| | | Dielectric constant (ε) of | | | 2.12 | 2.27 | 2.22 | 2.22 | 2.22 | 2.22 | 2.22 | |
| | | cured body of resin after heat | | | | | | | | | | |
| | | curing at 180° C. for 30 minutes | | | | | | | | | | |
| | | Dielectric loss tangent (tan δ) | | | 0.0006 | 0.0015 | 0.0012 | 0.0012 | 0.0012 | 0.0012 | 0.0012 | |
| | | of cured body of resin after | | | | | | | | | | |
| | | heat curing at 180° C. for 30 | | | | | | | | | | |
| | | minutes | | | | | | | | | | |
| | | Dielectric constant (ε) of | | | 2.60 | 2.89 | 2.85 | 2.85 | 2.85 | 2.85 | 2.85 | |
| | | coverlay film after heat curing | | | | | | | | | | |
| | | at 150° C. for 60 minutes | | | | | | | | | | |
| | | Dielectric loss tangent (tan δ) | | | 0.0027 | 0.0038 | 0.0035 | 0.0035 | 0.0035 | 0.0035 | 0.0035 | |
| | | of coverlay film after heat | | | | | | | | | | |
| | | curing at 150° C. for 60 minutes | | | | | | | | | | |
| | Adhesiveness | Peel adhesion strength of | | | 12 | 13 | 17 | 17 | 17 | 17 | 17 | |
| | | flexible copper clad laminate | | | | | | | | | | |
| | | (N/mm) | | | | | | | | | | |

| | | | | | | | |
|---|---|---|---|---|---|---|---|
| Solder heat resistance of flexible copper clad | X | ◯ | ◯ | ◯ | ◯ | ◯ | ◯ |
| laminate (° C.) | | | | | | | |
| Storage stability of adhesive composition at | ⊚ | ⊚ | ⊚ | X | Δ | X | X |
| low temperatures | | | | | | | |
| Storage stability of coverlay film | ◯ | ◯ | ◯ | ◯ | ◯ | ◯ | ◯ |
| Warpage of coverlay film | ⊚ | ⊚ | ⊚ | ⊚ | ⊚ | ⊚ | ⊚ |

From the results in the above Table 1 and Table 2, the adhesive compositions of Examples 1 to 11 and 13 to 28 showed excellent dielectric properties in both cases of the heat-curing at 150° C. for 60 minutes and the heat-curing at 180° C. for 30 minutes, and also showed excellent adhesiveness and solder heat resistance. In addition, the adhesive composition of Example 12 showed excellent dielectric properties in case of the heat-curing at 150° C. for 60 minutes, and also showed good adhesiveness and solder heat resistance. Moreover, the adhesive compositions of Examples 1 to 17 and 20 to 28 had good storage stability at low temperatures.

In addition, the laminates having adhesive layer of Examples 1 to 28 were excellent in dielectric properties and storage stability, and were suppressed in warpage.

On the other hand, the adhesive compositions of Comparative Examples 1 and 9 to 12 containing only the modified polypropylene-based resin and of Comparative Example 8 with the content of the unmodified polypropylene-based resin being outside the range of the present invention had poor dielectric properties, and the storage stability at low temperatures was also poor in Comparative Examples 9, 11, and 12. The adhesive compositions of Comparative Example 2 containing only the unmodified polypropylene-based resin and of Comparative Examples 6 and 7 with the content of the modified polypropylene-based resin being outside the range of the present invention had poor adhesiveness, and were inferior in at least one of dielectric properties and solder heat resistance. The adhesive composition of Comparative Example 3 containing no epoxy resin was inferior in adhesiveness and solder heat resistance.

### INDUSTRIAL APPLICABILITY

The adhesive composition according to the present invention shows good adhesiveness and storage stability at low temperatures, and is excellent in dielectric properties. The laminate having an adhesive layer using this adhesive composition exhibits little warpage even when the base film is thin; therefore the laminate is excellent in workability. Thus, the adhesive composition and the laminate with adhesive layer using the same according to the present invention are suitable for producing FPC-related products.

1. An adhesive composition, which comprises a modified polypropylene-based resin (A), an epoxy resin (B), and an unmodified polypropylene-based resin (C),
in which the modified polypropylene-based resin (A) is a resin resulting from graft-modification of an unmodified polypropylene-based resin (D) with a modifying agent comprising an α,β-unsaturated carboxylic acid or derivative thereof, and
which has a content of the modified polypropylene-based resin (A) of 10 parts by mass or more relative to 100 parts by mass of solid content of the adhesive composition, and
which has a content of the unmodified polypropylene-based resin (C) of 1 part by mass or more and 90 parts by mass or less relative to 100 parts by mass of solid content of the adhesive composition.

2. The adhesive composition according to claim 1, wherein the derivative of the α,β-unsaturated carboxylic acid is at least one selected from the group consisting of itaconic anhydride, maleic anhydride, aconitic anhydride, and citraconic anhydride.

3. The adhesive composition according to claim 1, wherein the grafted portions derived from the α,β-unsaturated carboxylic acid or derivative thereof are contained in a percentage of from 0.1 to 20 mass % relative to 100 mass % of the modified polypropylene-based resin (A).

4. The adhesive composition according to claim 1, wherein the epoxy resin (B) is a multifunctional epoxy resin having an alicyclic structure.

5. The adhesive composition according to claim 1, wherein the modified polypropylene-based resin (A) has a propylene copolymerization ratio of 70 mass % or less.

6. The adhesive composition according to claim 1, wherein the unmodified polypropylene-based resin (C) has a propylene copolymerization ratio of 70 mass % or less.

7. The adhesive composition according to claim 1, wherein the unmodified polypropylene-based resin (C) and the unmodified polypropylene-based resin (D) are each at least one selected from the group consisting of ethylene-propylene copolymers, propylene-butene copolymers, and ethylene-propylene-butene copolymers.

8. The adhesive composition according to claim 1, wherein the adhesive composition further comprises an antioxidant.

9. The adhesive composition according to claim 1, wherein the adhesive composition further comprises an organic solvent, wherein the modified polypropylene-based resin (A), the epoxy resin (B), and the unmodified polypropylene-based resin (C) are dissolved in the organic solvent.

10. The adhesive composition according to claim 9, wherein the organic solvent comprises an alicyclic hydrocarbon solvent that is methylcyclohexane and/or cyclohexane, and an alcohol-based solvent,
which has a content of the alicyclic hydrocarbon of 20 parts by mass or more and 90 parts by mass or less relative to 100 parts by mass of the organic solvent, and
which has a content of the alcohol-based solvent of 1 part by mass or more and 20 parts by mass or less relative to 100 parts by mass of the organic solvent.

11. The adhesive composition according to claim 9, wherein the organic solvent comprises toluene.

12. The adhesive composition according to claim 9, which has a solid content of 5 mass % or more and 50 mass % or less.

13. A laminate having an adhesive layer, which laminate comprises an adhesive layer formed of the adhesive composition according to claim 1, and a base film contacting at least one of the surfaces of the adhesive layer, wherein the adhesive layer is in B stage.

14. The laminate having an adhesive layer, according to claim 13, wherein the base film is at least one selected from the group consisting of a polyimide film, a polyether ether ketone film, a polyphenylene sulfide film, an aramid film, a polyethylene naphthalate film, a liquid crystal polymer film, a polyethylene terephthalate film, a polyethylene film, a polypropylene film, a silicone-treated release paper, a polyolefin resin coated paper, a TPX film, a fluorine-based resin film, and a copper foil.

15. A printed wiring board which comprises an adhesive layer formed of the adhesive composition according to claim 1.

16. A flexible flat cable which comprises an adhesive layer formed of the adhesive composition according to claim 1.
